(19) United States
(12) Patent Application Publication
(10) Pub. No.: US 2009/0011612 A1
(43) Pub. Date: Jan. 8, 2009

(54) METHOD OF SHORTENING PHOTORESIST COATING PROCESS

(75) Inventors: Chiun-Show Chen, Hsinchu City (TW); Chao-Ying Chung, Hsinchu County (TW); Ju-Te Chen, Tainan City (TW); Chao-Hsien Wu, Hsinchu City (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/773,879

(22) Filed: Jul. 5, 2007

(51) Int. Cl. H01L 21/31

(52) U.S. Cl. 438/782; 257/E21.259

(57) ABSTRACT

A method of shortening a photoresist coating process for a plurality of wafers is provided, wherein the photoresist coating process includes a first coating operation to a first wafer using a first photoresist liquid and a second coating operation to a second wafer using a second photoresist liquid. The method includes performing a dummy dispense operation of the second photoresist liquid within the period of the backend part of the first coating operation that needs no nozzle.

### BACKGROUND OF THE INVENTION

1. Field of Invention

This invention relates to an integrated circuit (IC) process, and more particularly to a method of shorting a photoresist coating process.

2. Description of Related Art

Photoresist material is a photosensitive material needed in a lithography process, while a lithography process is essential for definition of the patterns of a film or doped regions. Therefore, the photoresist material is very important in IC processes.

A lithography process typically includes coating a photoresist layer on a wafer, projecting light to the photoresist through a photomask to selectively photosensitize and transfer patterns to the same and then performing a development step. The photoresist coating step is accomplished in a machine equipped with a coater.

Generally, a dummy dispense operation is performed before each lot of wafers is coated with photoresist to prevent the nozzle from drying and purge the tip photoresist liquid having contacted with the air to keep a constant composition thereof, or to purge a photoresist liquid for later use of next photoresist liquid. The discharge rate of the photoresist liquid may also be measured with a dummy dispense operation. As shown in FIG. 3, after the photoresist coating of a lot A is done, a dummy dispense operation has to be performed prior to the photoresist coating of next lot (lot B). Since a dummy dispense operation takes a period of about 30 seconds at least, it is necessary to wait more time before next lot of wafers are coated. This not only increases the cycle time of the process and reduces the throughput, but also lowers the operation efficiency of the coating machine.

### SUMMARY OF THE INVENTION

Accordingly, the invention provides a method of shortening a photoresist coating process, which can decrease the cycle time and increase the operation efficiency of the coating machine.

The method of this invention is applied to a photoresist coating process for a plurality of wafers, which includes a first coating operation to a first wafer using a first photoresist liquid and a second coating operation to a second wafer using a second photoresist liquid. The method includes performing a dummy dispense operation of the second photoresist liquid within the period of the backend part of the first coating operation, wherein the backend part of the first coating operation needs no nozzle.

In an embodiment, the first wafer is the last-coated one of a first lot of wafers and the second wafer is the first-coated one of a second lot of wafers, wherein the second lot of wafers are coated after the first lot of wafers are all coated. In another embodiment, the first wafer is the last-coated one of a first section of wafers and the second wafer is the first-coated one of a second section of wafers, wherein the first and second sections of wafers belong to one lot of wafers and the second section of wafers are coated after the first section of wafers are all coated.

In an embodiment, the dummy dispense operation is programmed such that the end point thereof is close to that of the first coating operation. The period between the end of the first coating operation and the start of the second coating operation may be shorter than the duration of the dummy dispense operation.

In some embodiments, the first and the second photoresist liquids have different compositions.

In some embodiments, the backend part of the first coating operation includes spin-flattening the first photoresist liquid on the first wafer, cleaning the edge and the backside of the first wafer and curing the first photoresist liquid.

In some embodiments, the first and the second coating operations use the same nozzle or use different nozzles.

Since the dummy dispense operation of the second photoresist liquid is done within the period of the backend part of the first coating operation, the cycle time of the whole photoresist coating process is reduced, so that the throughput and the operation efficiency of the coating machine both can be increased.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a flow chart of a part of a photoresist coating process that utilizes a process shortening method according to an embodiment of this invention.

FIG. 2 shows a time program of a photoresist coating process that utilizes the process shortening method according to the embodiment of this invention.

FIG. 3 shows a time program of a photoresist coating process in the prior art.

### DESCRIPTION OF EMBODIMENTS

The following embodiment is intended to further explain this invention but not to limit the scope of the same.

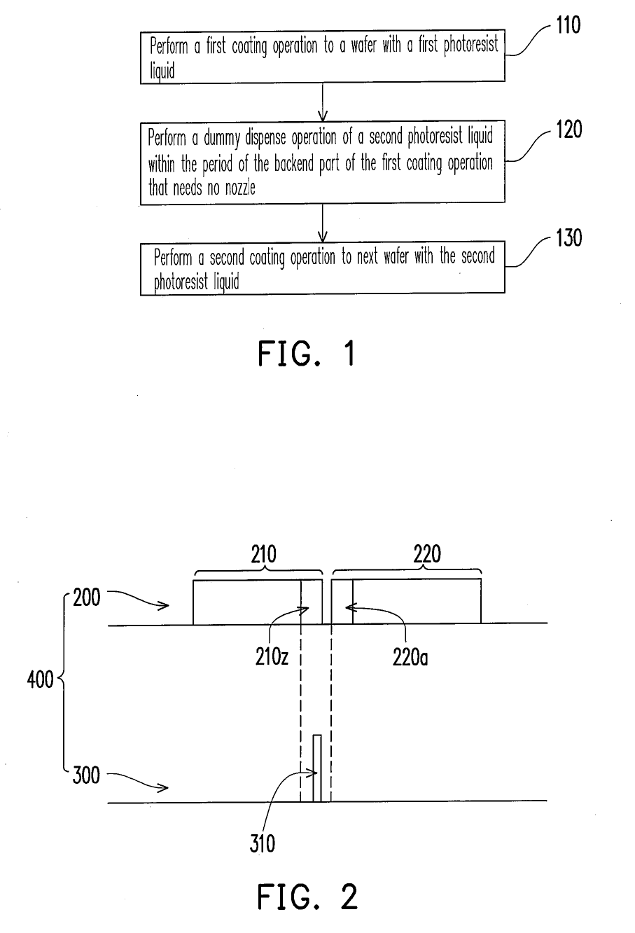

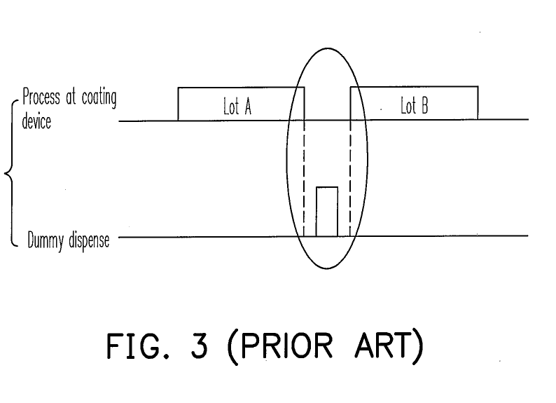

The method of this invention is applied to a photoresist coating process for a plurality of wafers. Referring to FIG. 1, in the first step 110, a first coating operation is performed to a wafer with a first photoresist liquid. Referring to FIG. 2, the photoresist coating process 400 may include a coating section 200 and a dummy dispense operation 300, wherein the coating section 200 includes a first coating procedure 210 using the first photoresist liquid and a second coating procedure 220 using a second photoresist liquid. The coating section 200 may further include an idle time (not shown) for wafer replacement. The above wafer may be the last-coated one of one lot or one section of wafers predetermined to coat with the first photoresist liquid, wherein the one section of wafers belong to one lot of wafers that include multiple sections of wafers. In general, the above wafer is the last-coated one of one group of wafers that is predetermined to coat with the first photoresist liquid. In the case of FIG. 2, the first coating procedure 210 uses the first photoresist liquid, wherein the coating operation of the last wafer in the first coating procedure 210 is labeled with “210z”.

A photoresist liquid typically includes a resin, a photosensitive agent and a solvent. Each coating operation may include steps of solvent application, photoresist application, photoresist spin-flattening, wafer cleaning, photoresist curing and so forth, wherein no nozzle is needed after the photoresist application. These steps are done to one wafer, possibly all on the same coater. The dummy dispense operation 300 is not done to a wafer on a coater but is done in a standby region beside the coater.

In next step 120, a dummy dispense operation of a second photoresist liquid is performed within the period of the backend part of the first coating operation that needs no nozzle. The backend part of the first coating operation includes the photoresist spin-flattening, wafer cleaning and photoresist curing steps each needing no nozzle. In the photoresist spin-flattening step, the spinning rate of the spinner is adjusted to flatten the first photoresist liquid on the surface of the wafer. In the wafer cleaning step, the edge and the backside of the wafer are cleaned to remove the photoresist liquid thereon. In the photoresist curing step, the solvent in the first photoresist liquid is evaporated in the assist of spinning or heating. After the photoresist application of the first coating operation is finished, the nozzle is moved aside from above the wafer to be in an idle state. Therefore, within the period of the backend part of the first coating operation, the dummy dispense operation of the next (second) photoresist liquid can be conducted at the nozzle. Alternatively, the second coating operation using the second photoresist liquid uses a nozzle different from that used in the first coating operation using the first photoresist liquid. In the case illustrated by FIG. 2, the coating procedure 210 uses the first photoresist liquid. The dummy dispense operation 310 of the second photoresist liquid is conducted within the period of the backend part of the first coating operation 210z that needs no nozzle.

In next step 130, a second coating operation is performed to next wafer with the second photoresist liquid, which may have a composition different from that of the first photoresist liquid. The second coating operation can be conducted in the same coating machine performing the first coating operation. Since the dummy dispense operation has been finished within the period of the backend part of the first coating operation, it is not necessary to wait for a dummy dispense operation after the first coating operation is finished. Therefore, the second coating operation to the next wafer can be started soon. The next wafer may be the first-coated one of next lot of wafers or of next section of wafers in the same lot, wherein the next lot or next section of wafers are predetermined to coat with the second photoresist liquid. Accordingly, the above next wafer is the first-coated one of one group of wafers that is predetermined to coat with the next (second) photoresist liquid. Referring to FIG. 2 again, after the first coating operation 210z is finished, the second coating operation 220a is started after a short period that is required possibly for wafer transfer.

In an embodiment, the period of the backend part of the first coating operation that needs no nozzle is longer than the duration of the dummy dispense operation. It is also possible to utilize optimized programming to control the start time of the dummy dispense operation such that the end point thereof is close to, preferably about the same as, the end point of the first coating operation. FIG. 2 shows an example where the end point of the dummy dispense operation 310 is about the same as that of the coating operation 210z. Thus, after the dummy dispense operation of the second photoresist liquid is performed at the nozzle, the nozzle can be immediately moved over the coater to perform the second coating operation. The period of the backend part of the first coating operation that needs no nozzle may alternatively be shorter than the duration of the dummy dispense operation. In such a case, the period between the end of the first coating operation and the start of the second coating operation can still be shorter than the duration of the dummy dispense operation, because the dummy dispense operation of the second photoresist liquid is started within the period of the backend part of the first coating operation. Consequently, the cycle time of the photoresist coating process can be reduced.

An example is provided below to further explain the method of this invention. Referring to Table 1, the exemplary photoresist coating operation includes 14 stages.

TABLE 1

| No. of stage | Period (s) | Spinning rate (rpm) |
|---|---|---|
| 1 | 1 | 1000 |
| 2 | 4 | 80 |
| 3 | 1 | 600 |
| 4 | 0.1 | 1000 |
| 5 | 1.3 | 2600 |
| 6 | 1 | 300 |
| 7 | 27 | 1877 |
| 8 | 8 | 1877 |
| 9 | 1 | 1350 |
| 10 | 1 | 1000 |
| 11 | 5 | 1000 |
| 12 | 1 | 1000 |
| 13 | 5 | 1500 |
| 14 | 1 | 0 |

In this example, the stages 1-3 belong to the solvent application step, wherein the solvent can dissolve the photoresist material and reduce the amount of the photoresist liquid required. The stages 4-5 belong to the photoresist application step, wherein the nozzle for discharging the photoresist liquid may be positioned over the center of the wafer. The spinning rate is reduced and the nozzle is moved aside the wafer in the stage 6. The spinning rate of the spinner is varied to spin-flat the photoresist liquid on the surface of the wafer in the stages 7-9. The edge and the backside of the wafer are cleaned in the stages 10-12, the solvent is removed in the assist of wafer spinning to dry the coated photoresist layer in the stage 13. The spinner is stopped in the step 14, thus completing the photoresist coating operation.

Accordingly, the nozzle is idle aside and can be controlled to perform the dummy dispense operation of the next photoresist liquid since the stage 7. In this example, the dummy dispense operation takes 30.4 seconds, and the stages 7-14 together take about 49 seconds. That is, the dummy dispense operation of the next photoresist liquid can be finished before the backend part of the first coating operation is finished. Therefore, after the first coating operation is finished, it is of no need to wait for a dummy dispense operation of the next photoresist liquid that would take 30.4 seconds, and the next wafer can be loaded in the coater to coat with the second photoresist liquid immediately after the precedent wafer is moved out of the coater. In a case where one coating machine includes three coaters and the photoresist liquid is switched 21 times in one day, each machine can save totally 1915 (=30.4×3×21) seconds in one day.

The above example is merely the result of applying this invention to a specific photoresist coating operation conducted in a specific machine in the fab. However, this invention is not limited to apply to such a system, but can be widely applied to various coating machines used in various types of fabs. With this invention, the cycle time of a photoresist coating process for a plurality of wafers can be reduced, so that the throughput and the operation efficiency of the coating machine both can be increased.

This invention has been disclosed above in the preferred embodiments, but is not limited to those. It is known to persons skilled in the art that some modifications and innovations may be made without departing from the spirit and scope of this invention. Hence, the scope of the present invention should be defined by the following claims.

What is claimed is:

1. A method of shortening a photoresist coating process for a plurality of wafers, wherein the photoresist coating process includes a first coating operation to a first wafer using a first photoresist liquid and a second coating operation to a second wafer using a second photoresist liquid, the method comprising:
performing a dummy dispense operation of the second photoresist liquid within a period of a backend part of the first coating operation, wherein the backend part of the first coating operation needs no nozzle.

2. The method of claim 1, wherein the first wafer is a last-coated wafer of a first lot of wafers and the second wafer is a first-coated wafer of a second lot of wafers that are coated after the first lot of wafers are all coated.

3. The method of claim 1, wherein the first wafer is a last-coated wafer of a first section of wafers and the second wafer is a first-coated wafer of a second section of wafers, wherein the first and second sections of wafers belong to one lot of wafers and the second section of wafers are coated after the first section of wafers are all coated.

4. The method of claim 1, wherein the dummy dispense operation is programmed such that an end point thereof is close to an end point of the first coating operation.

5. The method of claim 1, wherein a period between an end of the first coating operation and a start of the second coating operation is shorter than a duration of the dummy dispense operation.

6. The method of claim 1, wherein the first photoresist liquid and the second photoresist liquid have different compositions.

7. The method of claim 1, wherein the backend part of the first coating operation includes steps of spin-flattening the first photoresist liquid on the first wafer, cleaning an edge and a backside of the first wafer, and curing the first photoresist liquid.

8. The method of claim 1, wherein the first coating operation and the second coating operation use the same nozzle or use different nozzles.
